(19) United States
(12) Patent Application Publication
(10) Pub. No.: US 2022/0165562 A1
(43) Pub. Date: May 26, 2022

(54) CLEANING LIQUID NOZZLE, CLEANING APPARATUS, AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Ho-Young Kim, Seoul (KR); Chae Lyoung Kim, Hwaseong-Si (KR); Tae-Hong Kim, Seoul (KR); Youngjun Kim, Seoul (KR); Boun Yoon, Seoul (KR); Sol Han, Seoul (KR); Joonoh Kim, Geumjeong-Gu (KR)

(73) Assignee: SEOUL NATIONAL UNIVERSITY, Seoul (KR)

(21) Appl. No.: 17/650,710

(22) Filed: Feb. 11, 2022

Related U.S. Application Data
(63) Continuation of application No. 16/201,654, filed on Nov. 27, 2018.

(30) Foreign Application Priority Data
May 10, 2018 (KR) 10-2018-0053886

(51) Int. Cl. H01L 21/02; B08B 3/02; B08B 5/02; H01L 21/67; B05B 1/14; B05B 7/08; B05B 7/00

(52) U.S. Cl. CPC H01L 21/02057; B08B 3/024; B08B 5/02; B05B 7/0075; B05B 1/14; B05B 7/08; H01L 21/67051

(57) ABSTRACT

A cleaning apparatus includes a gas supply line and a cleaning liquid supply line. A nozzle is connected to the gas and the cleaning liquid supply lines. The nozzle applies the cleaning liquid to a substrate. A gas entrance port at a top of a body of the nozzle is connected to the gas supply line. A first cleaning liquid entrance port is disposed on a sidewall of the nozzle body and is connected to the cleaning liquid supply line. A fluid injection port is disposed at a bottom of the nozzle body and discharges both the gas and the cleaning liquid. An internal passage of the nozzle body connects each of the gas entrance port and the first cleaning liquid entrance port to the fluid injection port. The fluid injection port has a diameter that is greater than a diameter of the first cleaning liquid entrance port.

### CROSS-REFERENCE TO RELATED APPLICATION

This U.S. nonprovisional application is a Continuation of co-pending U.S. patent application Ser. No. 16/201,654, filed on Nov. 27, 2018, which claims priority under 35 U.S.C § 119 to Korean Patent Application No. 10-2018-0053886 filed on May 10, 2018 in the Korean Intellectual Property Office, the entire contents of which are hereby incorporated by reference.

### TECHNICAL FIELD

The present disclosure relates to semiconductor device manufacturing and, more specifically, to a cleaning liquid nozzle, a cleaning apparatus, and a method of manufacturing a semiconductor device using the same.

### DISCUSSION OF THE RELATED ART

Modern semiconductor devices have a high degree of integration. As such, these devices have fine patterns, multi-layered circuits, and so forth. As semiconductor device fabrication may lead to contamination of the patterns by particles which are released during processing, various cleaning processes for removing these contaminating particles have been developed. These cleaning processes may include a wet cleaning process and/or a dry cleaning process. In particular, deionized water is often used to perform the wet cleaning process.

### SUMMARY

A cleaning apparatus includes a gas supply line providing a gas. A cleaning liquid supply line provides a cleaning liquid. A nozzle is connected to both the gas supply line and the cleaning liquid supply line. The nozzle is configured to apply the cleaning liquid to a substrate. The nozzle includes a nozzle body. A gas entrance port is disposed at a top end of the nozzle body and is connected to the gas supply line. A first cleaning liquid entrance port is disposed on a first sidewall of the nozzle body and is connected to the cleaning liquid supply line. A fluid injection port is disposed at a bottom end of the nozzle body and is configured to discharge both the gas and the cleaning liquid. An internal passage is disposed within the nozzle body. The internal passage connects each of the gas entrance port and the first cleaning liquid entrance port to the fluid injection port. The fluid injection port has a diameter that is greater than a diameter of the first cleaning liquid entrance port.

A cleaning liquid nozzle includes a nozzle body. A gas entrance port is disposed at a top end of the nozzle body. The gas entrance port is connected to a gas supply line configured to provide a gas. A cleaning liquid entrance port is disposed on a sidewall of the nozzle body and is connected to a cleaning liquid supply line configured to provide a cleaning liquid. A fluid injection port is disposed at a bottom end of the nozzle body. The fluid injection port is configured to discharge the gas and the cleaning liquid. An internal passage is disposed in the nozzle body. The internal passage connects both the gas entrance port and the cleaning liquid entrance port to the fluid injection port. The fluid injection port has a diameter that is less than a diameter of the gas entrance port and greater than a diameter of the cleaning liquid entrance port.

A method of manufacturing a semiconductor device includes polishing a substrate. A gas is provided from a gas supply line to a nozzle via a gas entrance port of the nozzle. The gas entrance port is disposed at a top end of the nozzle. A cleaning liquid is provided to the polished substrate in the form of a spray emanating from a fluid injection port of the nozzle. The cleaning liquid is supplied from a cleaning liquid supply line and the cleaning liquid enters the nozzle via a cleaning liquid entrance port that is disposed on a sidewall of the nozzle. The fluid injection port is disposed at a bottom end of the nozzle. The gas is carried from the gas entrance port to the fluid injection port by an internal passage of the nozzle and the cleaning liquid is carried from the cleaning liquid entrance port to the fluid injection port by the internal passage of the nozzle. A diameter of the fluid injection port is greater than a diameter of the cleaning liquid entrance port.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view illustrating a semiconductor device manufacturing facility according to exemplary embodiments of the present inventive concept;

FIG. 2 is a cross-sectional view illustrating an example of a cleaning apparatus shown in FIG. 1 according to exemplary embodiments of the present inventive concept;

FIG. 3 is a table illustrating an influence on particle removal efficiency based on cleaning liquid pressure and gas pressure;

FIG. 4 is a graph illustrating an influence on particle removal efficiency based on height of a nozzle relative to a substrate;

FIG. 5 is a cross-sectional view illustrating an example of a nozzle shown in FIG. 2 according to exemplary embodiments of the present inventive concept;

FIG. 6 is a graph illustrating an influence on particle removal efficiency based on a ratio of a third diameter of a fluid injection port to a second diameter of a first cleaning liquid entrance port;

FIG. 7 is a graph illustrating an influence on particle removal efficiency based on a ratio of a first diameter of a gas entrance port to a third diameter of a fluid injection port;

FIG. 8 is a graph illustrating an influence on particle removal efficiency based on a ratio of first and second lengths;

FIG. 9 is a graph illustrating an influence on particle removal efficiency based on a ratio of a third length to a second length;

FIG. 10 is a cross-sectional view illustrating an example of a nozzle shown in FIG. 2 according to exemplary embodiments of the present inventive concept;

FIG. 11 is a cross-sectional view illustrating an example of a nozzle shown in FIG. 2 according to exemplary embodiments of the present inventive concept;

FIGS. 12 and 13 are exploded and combined perspective views illustrating various elements of FIG. 11 according to exemplary embodiments of the present inventive concept; and

FIG. 14 is a flow chart illustrating a method of manufacturing a semiconductor device, according to exemplary embodiments of the present inventive concept.

### DETAILED DESCRIPTION OF EMBODIMENTS

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

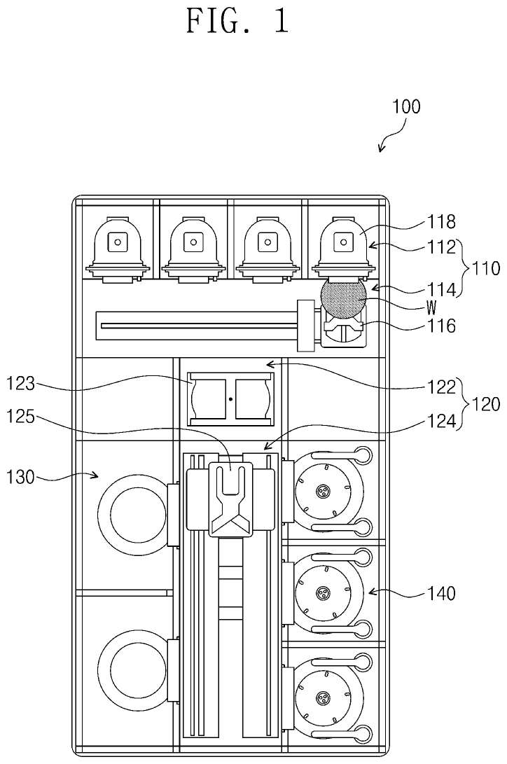

FIG. 1 is a plan view illustrating a semiconductor device manufacturing facility 100 according to exemplary embodiments of the present inventive concept.

Referring to FIG. 1, the manufacturing facility 100 may include wet cleaning equipment or wet etching equipment. Alternatively, the manufacturing facility 100 may include chemical mechanical polishing equipment. According to an exemplary embodiment of the present inventive concept, the manufacturing facility 100 may include an index apparatus 110, a transfer apparatus 120, a polishing apparatus 130, and a cleaning apparatus 140.

The index apparatus 110 may temporarily store a carrier 118. The carrier 118 may load a substrate W. According to an exemplary embodiment of the present inventive concept the index apparatus 110 may include a load port 112 and a transfer frame 114. The load port 112 may accommodate the carrier 118. The carrier 118 may include a front opening unified pod (FOUP). The transfer frame 114 may have an index arm 116. The index arm 116 may retrieve the substrate W from the carrier 118 and deliver the substrate W to the transfer apparatus 120. Alternatively, or additionally, the index arm 116 may bring the substrate W into the carrier 118.

The transfer apparatus 120 may transfer the substrate W to the polishing apparatus 130 and the cleaning apparatus 140. According to an exemplary embodiment of the present inventive concept, the transfer apparatus 120 may include a buffer chamber 122 and a transfer chamber 124. The buffer chamber 122 may be disposed between the transfer frame 114 and the transfer chamber 124. The buffer chamber 122 may include a buffer arm 123. The buffer arm 123 may receive the substrate W from the index arm 116. The transfer chamber 124 may be disposed between the polishing apparatus 130 and the cleaning apparatus 140. The transfer chamber 124 may include a transfer arm 125. The transfer arm 125 may provide the polishing apparatus 130 with the substrate W on the buffer arm 123. The transfer arm 125 may transfer the substrate W from the polishing apparatus 130 to the cleaning apparatus 140. The transfer arm 125 may also transfer the substrate W from the cleaning apparatus 140 to the buffer arm 123. The buffer arm 123 may transfer the substrate W to the index arm 116.

The polishing apparatus 130 may be disposed on one side of the transfer chamber 124. The polishing apparatus 130 may polish the substrate W. For example, the polishing apparatus 130 may be a chemical mechanical polishing (CMP) apparatus. Alternatively, the polishing apparatus 130 may be disposed on a distal end of the transfer chamber 124, wherein the distal end faces the buffer chamber 122.

The cleaning apparatus 140 may be disposed on another side of the transfer chamber 124. The cleaning apparatus 140 may clean and/or etch the substrate W. According to an exemplary embodiment of the present inventive concept the cleaning apparatus 140 may wet-clean the substrate W. According to an exemplary embodiment of the present inventive concept, the cleaning apparatus 140 may dry-clean the substrate W.

A drying apparatus may be provided between the buffer chamber 122 and the polishing apparatus 130 or between the buffer chamber 122 and the cleaning apparatus 140. The drying apparatus may dry the substrate W. For example, the drying apparatus may include a supercritical drying apparatus. Alternatively, the drying apparatus may include a baking and/or a heating device.

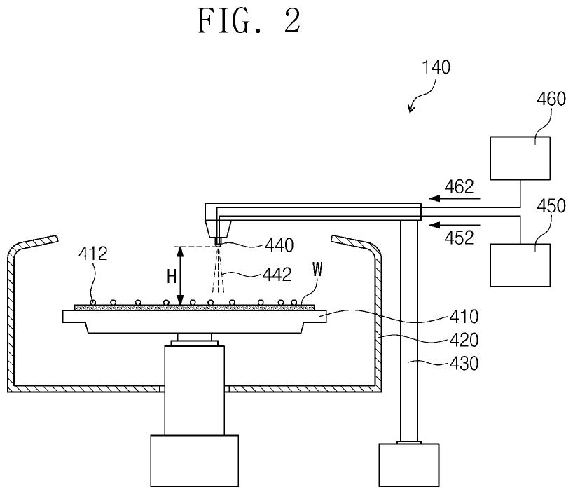

FIG. 2 is a cross-sectional view illustrating an example of the cleaning apparatus 140 shown in FIG. 1.

Referring to FIG. 2, the cleaning apparatus 140 may include a chuck 410, a bowl 420, an arm 430, a nozzle 440, a cleaning liquid supply 450, and a gas supply 460.

The chuck 410 may load the substrate W. The chuck 410 may rotate the substrate W. For example, the chuck 410 may rotate the substrate W at a rate within a range of about 10 rpm to about 6000 rpm. As the chuck 410 rotates the substrate W, centrifugal force may cause a cleaning liquid 452 to move along the substrate W. The cleaning liquid 452 may thereby clean the substrate W.

The bowl 420 may surround the substrate W. The cleaning liquid 452 may move from the substrate W toward the bowl 420. The bowl 420 may catch the cleaning liquid 452 that is spun from the substrate W during rotation. The bowl 420 may then drain the cleaning liquid 452 below the chuck 410. The bowl 420 may prevent contamination of the substrate W.

The arm 430 may be fixedly disposed outside of the bowl 420 and may extend onto the chuck 410. The nozzle 440 may be connected to a tip of the arm 430. The arm 430 may drive the nozzle 440 to move from a center of the substrate W toward an edge of the substrate W.

The nozzle 440 may use the cleaning liquid 452 to clean the substrate W. The cleaning liquid 452 may be provided onto the substrate W in the form of droplets or as a mist. For example, the nozzle 440 may produce a spray 442 of the cleaning liquid 452. The spray 442 may be provided onto the substrate W. As the nozzle 440 sweeps over the substrate W, the spray 442 may remove particles 412 from the substrate W.

The cleaning liquid supply 450 may be connected to the nozzle 440. The cleaning liquid supply 450 may provide the nozzle 440 with the cleaning liquid 452. The cleaning liquid supply 450 may provide the cleaning liquid 452 at a pressure within a range of about 1 to 10 bars. The cleaning liquid 452 may include deionized water containing carbon dioxide (CO₂).

The gas supply 460 may be connected to the nozzle 440. The gas supply 460 may provide the nozzle 440 with a gas 462. The gas 462 may include a nitrogen gas. Alternatively, the gas 462 may include an inert gas of argon.

The gas 462 and the cleaning liquid 452 may be delivered to the nozzle 440 under pressure.

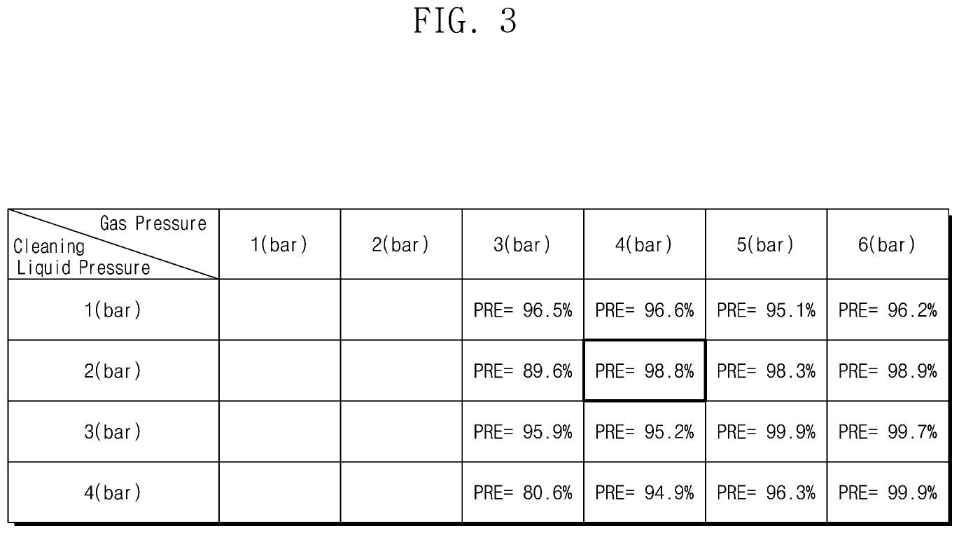

FIG. 3 is a table illustrating how particle removal efficiency is influenced by the pressure of the cleaning liquid 452 and the pressure of the gas 462.

Referring to FIG. 3, when the pressure of the gas 462 is equal to or greater than about 3 bars, the particle removal efficiency (PRE) may be equal to or greater than about 80%. When the pressure of the gas 462 is equal to or less than about 2 bars, no particle removal efficiency may be obtained. This may indicate that, when the pressure of the gas 462 is equal to or less than about 2 bars, the cleaning liquid 452 might not be converted into the spray 442, which may result in reduction in particle removal efficiency. A field emission scanning electron microscope (FESEM) may be used to determine the particle removal efficiency before and after a suspension of chemical mechanical polishing (CMP) is cleaned on the substrate W. For example, the particle removal efficiency may be expressed by a percentage of a cleaning area of the substrate W (e.g., a cleaned area from which the particles 412 are removed) to a whole area of the substrate W (e.g., a contaminated area by the particles 412).

According to an exemplary embodiment of the present inventive concept, a threshold value of the particle removal efficiency may be set to about 98%. The threshold value of the particle removal efficiency may be used as a criterion for determining normality of a cleaning process. For example, when the pressure of the gas 462 is about 4 bars, and when the pressure of the cleaning liquid 452 is about 2 bars, the particle removal efficiency may be about 98.8% greater than the threshold value. The pressure of the cleaning liquid 452 may be proportional to a consumption amount of the cleaning liquid 452. In addition, the pressure of the gas 462 may be proportional to a consumption amount of the gas 462. When the pressure of the gas 462 is about 4 bars, and when the pressure of the cleaning liquid 452 is about 2 bars, the consumption amount of each of the cleaning liquid 452 and the gas 462 may be minimal, and productivity of a cleaning process may be maximized. When the pressure of the gas 462 is equal to or greater than about 5 bars, and when the pressure of the cleaning liquid 452 is equal to or greater than about 3 bars, the particle removal efficiency may be increased to about 98% or higher. However, the consumption amount of each of the cleaning liquid 452 and the gas 462 may become increased, and the productivity of a cleaning process may become reduced.

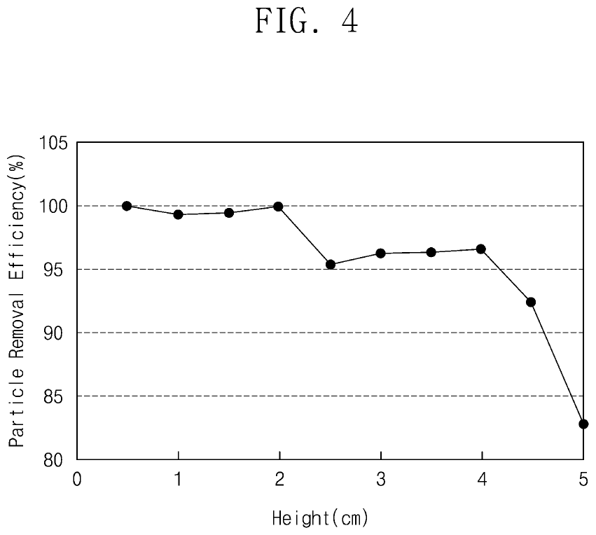

FIG. 4 is a graph illustrating how particle removal efficiency is influenced by a height H of the nozzle 440 relative to the substrate W.

Referring to FIG. 4, when the height H of the nozzle 440 is equal to or less than about 2 cm, the particle removal efficiency may be equal to or greater than about 98%. When the height H of the nozzle 440 is equal to or greater than about 2.5 cm, the particle removal efficiency may be reduced to about 96% or lower.

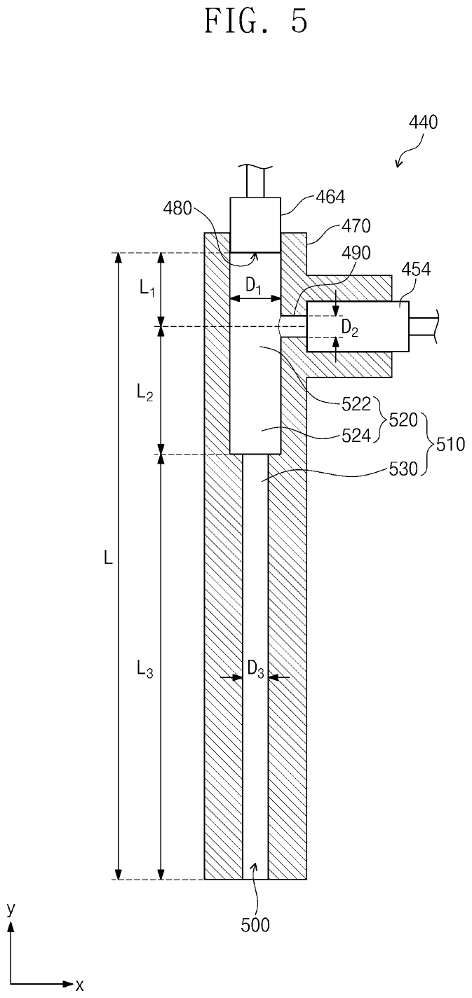

FIG. 5 is a cross-sectional view illustrating an example of the nozzle 440 shown in FIG. 2.

Referring to FIG. 5, the nozzle 440 may include a two-fluid nozzle and/or an air atomizing nozzle. According to an exemplary embodiment of the present inventive concept, the nozzle 440 may include a nozzle body 470, a gas entrance port 480, a first cleaning liquid entrance port 490, a fluid injection port 500, and an internal passage 510.

The nozzle body 470 may be formed of a conductive material such as a metal or carbon nanotubes. The nozzle body 470 may be electrically grounded. The nozzle body 470 may have a length L ranging from about 70 mm to about 100 mm. A first cleaning liquid line fitting 454 and a gas line fitting 464 may be coupled to the nozzle body 470. The first cleaning liquid line fitting 454 may be connected to the cleaning liquid supply 450 through a liquid line, and the gas line fitting 464 may be connected to the gas supply 460 through a gas line.

The gas entrance port 480 may be disposed at a top end of the nozzle body 470. The gas entrance port 480 may be disposed in a second direction y. The gas line fitting 464 may be engaged within the gas entrance port 480. The gas entrance port 480 may have a first diameter D₁ ranging from about 3 mm to about 8 mm.

The first cleaning liquid entrance port 490 may be disposed on one sidewall of the nozzle body 470. The first cleaning liquid entrance port 490 may be disposed in a first direction x that is different from the second direction y. For example, the first direction x and the second direction y may be orthogonal. The first cleaning liquid line fitting 454 may be mounted on the first cleaning liquid entrance port 490. The first cleaning liquid entrance port 490 may have a second diameter D₂ that is less than the first diameter D₁ of the gas entrance port 480. For example, the second diameter D₂ of the first cleaning liquid entrance port 490 may fall within a range from about 2.5 mm to about 3 mm. When the second diameter D₂ of the first cleaning liquid entrance port 490 is greater than about 3 mm, the cleaning liquid 452 may be largely consumed.

The fluid injection port 500 may be disposed at a bottom end of the nozzle body 470. The fluid injection port 500 may be disposed in the same direction in which the gas entrance port 480 is disposed. For example, the fluid injection port 500 may be disposed in the second direction y. The fluid injection port 500 may discharge or inject the gas 462 and the cleaning liquid 452. According to an exemplary embodiment of the present inventive concept, the fluid injection port 500 may have a third diameter D₃ that is less than the first diameter D₁ of the gas entrance port 480 and greater than the second diameter D₂ of the first cleaning liquid entrance port 490. For example, the third diameter D₃ may fall within a range from about 3 mm to about 4.5 mm, which is about 1.2 to 1.5 times greater than the second diameter D₂.

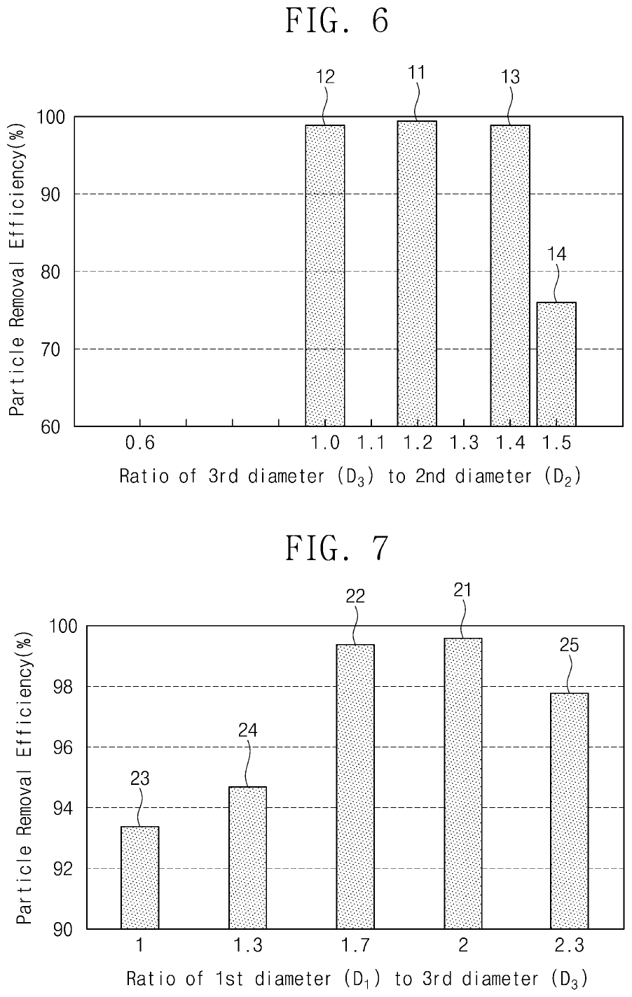

FIG. 6 is a graph illustrating how particle removal efficiency is influenced by a ratio of the third diameter D₃ of the fluid injection port 500 to the second diameter D₂ of the first cleaning liquid entrance port 490.

Referring to FIG. 6, when the ratio of the third diameter D₃ to the second diameter D₂ is in a range of about 1.0 to about 1.4 (e.g., 1.0, 1.2, and 1.4), the particle removal efficiency may fall within a range equal to or greater than the threshold value, which ranges from about 98% to about 99.9% (e.g., 99.9%, 98%, and 98% as designated by reference numerals 11, 12, and 13). For example, the second diameter D₂ of the first cleaning liquid entrance port 490 may be in a range of about 2.5 mm to about 3.0 mm, and the third diameter D₃ of the fluid injection port 500 may be in a range of about 2.5 mm to about 4.2 mm.

When the ratio of the third diameter D₃ to the second diameter D₂ is about 1.5, the particle removal efficiency may be about 76%, as designated by a reference numeral 14, which is less than the threshold value. For example, when the second diameter D₂ is about 2.5 mm, the third diameter D₃ may be about 3.75 mm. When the second diameter D₂ is about 3 mm, the third diameter D₃ may be about 4.5 mm.

When the ratio of the third diameter D₃ to the second diameter D₂ is about 0.6, no particle removal efficiency may be obtained. When the second diameter D₂ is greater than the third diameter D₃, the particle removal efficiency may become reduced due to the fact that the cleaning liquid 452 is not converted into the spray 442.

FIG. 7 id a graph illustrating how particle removal efficiency is influenced by a ratio of the first diameter D₁ of the gas entrance port 480 to the third diameter D₃ of the fluid injection port 500.

Referring to FIG. 7, when the ratio of the first diameter D₁ to the third diameter D₃ is about 2, the particle removal efficiency may be about 99.5%, as designated by a reference numeral 21, which is greater than the threshold value. The third diameter D₃ may be about 0.5 times the first diameter D₁. For example, when the third diameter D₃ is about 3 mm, the first diameter D₁ may be about 6 mm. The third diameter D₃ may be about 4.2 mm, and the first diameter D₁ may be about 8.4 mm. When the ratio of the first diameter D₁ to the third diameter D₃ is about 1.7, the particle removal efficiency may be about 99.2%, as designated by a reference numeral 22, which is greater than the threshold value. The third diameter D₃ may be about 0.4 times the first diameter D₁. For example, when the third diameter D₃ is about 3 mm, the first diameter D₁ may be about 5.1 mm. When the third diameter D₃ is about 4.2 mm, the first diameter D₁ may be about 7.14 mm. When the ratio of the first diameter D₁ to the third diameter D₃ is about 1, 1.3, and 2.3, the particle removal efficiency may be, as designated by reference numerals 23, 24, and 25, less than the threshold value.

Referring back to FIG. 5, the internal passage 510 may penetrate the nozzle body 470. The internal passage 510 may connect both the gas entrance port 480 and the first cleaning liquid entrance port 490 to the fluid injection port 500. The internal passage 510 may extend in the second direction y. For example, the internal passage 510 may include a fluid supply zone 520 and a fluid acceleration zone 530. The fluid supply zone 520 may be a region into which the gas 462 and the cleaning liquid 452 are introduced. For example, the fluid supply zone 520 of the internal passage 510 may have a diameter that is the same as the first diameter D₁ of the first cleaning liquid entrance port 490. For example, the fluid supply zone 520 may include a gas supply zone 522 and a fluid mixture zone 524. The gas supply zone 522 may be disposed on the fluid mixture zone 524. The gas supply zone 522 may have a first length L₁ from the gas entrance port 480 to a center of the first cleaning liquid entrance port 490. The first length L₁ may be in a range of about 5 mm to about 15 mm.

The fluid mixture zone 524 may be disposed between the gas supply zone 522 and the fluid acceleration zone 530. The fluid mixture zone 524 may have a second length L₂ from the center of the first cleaning liquid entrance port 490 to the fluid acceleration zone 530. The second length L₂ may be in a range of about 5 mm to about 15 mm.

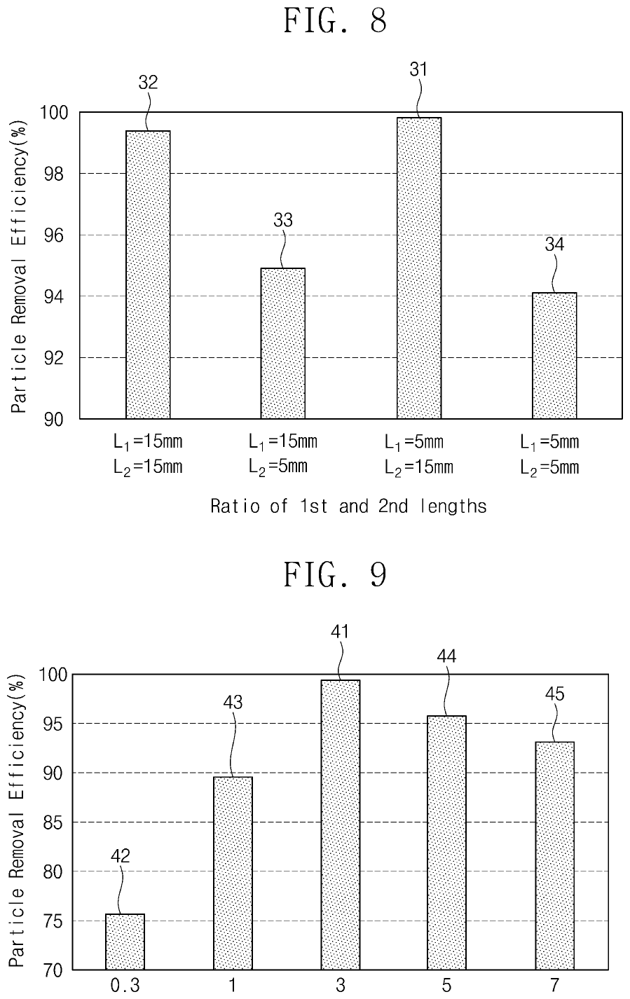

FIG. 8 is a graph illustrating how particle removal efficiency is influenced by a ratio of the first and second lengths L₁ and L₂.

Referring to FIG. 8, when the first length L₁ is about 5 mm and the second length L₂ is about 15 mm, the particle removal efficiency may be about 99.9%, as designated by a reference numeral 31, which is greater than the threshold value. The second length L₂ may be about 3 times greater than the first length L₁. When each of the first and second lengths L₁ and L₂ is about 15 mm, the particle removal efficiency may be about 99.5%, as designated by a reference numeral 32, which is greater than the threshold value. When the first length L₁ is about 15 mm and the second length L₂ is about 5 mm, the particle removal efficiency may be about 95%, as designated by a reference numeral 33, less than the threshold value. The second length L₂ may be less than about one-third the first length L₁. When each of the first and second lengths L₁ and L₂ is about 5 mm, the particle removal efficiency may be about 94% as designated by a reference numeral 34. When the second length L₂ of the fluid mixture zone 524 less than about 15 mm, the fluid mixture zone 524 may reduce a mixing time for the gas 462 and the cleaning liquid 452, which may result in decrease in production amount of the spray 442.

Referring again to FIG. 5, the fluid acceleration zone 530 may be disposed between the fluid mixture zone 524 and the fluid injection port 500. The fluid acceleration zone 530 may have a third length L₃. The third length L₃ may be in a range of about 50 mm to about 100 mm. The fluid acceleration zone 530 may accelerate the flow of the gas 462 and the cleaning liquid 452.

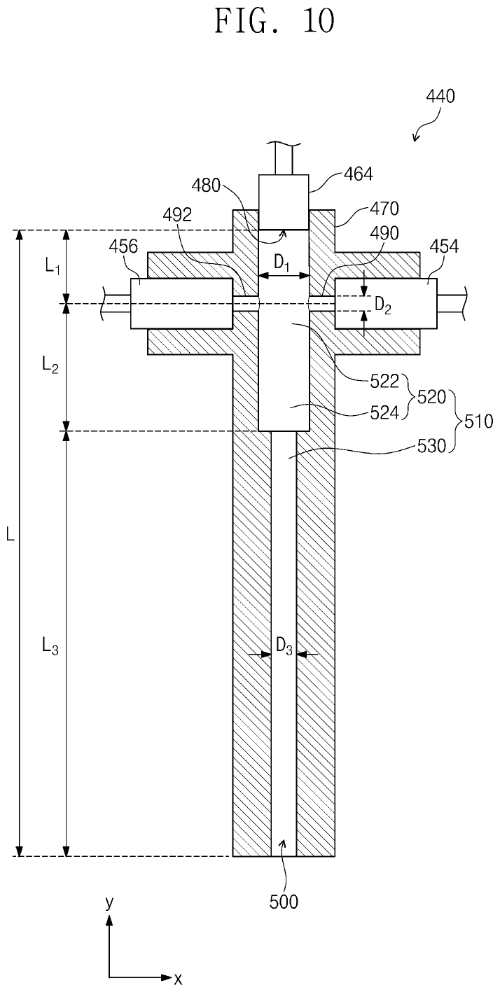

FIG. 9 is a graph illustrating how particle removal efficiency is influenced by a ratio of the third length L₃ to the second length L₂.

Referring to FIG. 9, when the ratio of the third length L₃ to the second length L₂ is about 3, the particle removal efficiency may be about 99%, as designated by a reference numeral 41, which is greater than the threshold value. The third length L₃ may be about 3 times greater than the second length L₂. For example, when the second length L₂ is about 15 mm, the third length L₃ may fall within a range from about 40 mm to about 50 mm. When the first length L₁ is about 5 mm, the second length L₂ is about 15 mm, and the third length L₃ is in a range of about 40 mm to about 50 mm, a ratio of the sum L₁+L₂ of the first and second lengths L₁ and L₂ to the third length L₃ may fall within a range from about 2 to about 2.5.

When the ratio of the third length L₃ to the second length L₂ is about 0.3, 1, 5, and 6.7, the particle removal efficiency may be about 95% or less, as designated by reference numerals 42, 43, 44, and 45, which is less than the threshold value. When the ratio of the third length L₃ to the second length L₂ is greater than about 3.3, the particle removal efficiency may become decreased, as designated by reference numerals 44 and 45, due to reduction in the fluid velocity of the gas 462 and the cleaning liquid 452. When the ratio of the third length L₃ to the second length L₂ is less than about 3, the particle removal efficiency may become decreased, as designated by reference numerals 42 and 43, due to reduction in directionality of the spray 442.

Referring back again to FIG. 5, the fluid acceleration zone 530 of the internal passage 510 may have a diameter that is the same as the third diameter D₃ of the fluid injection port 500. For example, the fluid acceleration zone 530 of the internal passage 510 may have a diameter of about 3 mm to about 4.5 mm.

FIG. 10 is a cross-sectional view illustrating an example of the nozzle 440 shown in FIG. 2.

As stated above, the first cleaning liquid entrance port 490 may be disposed on one sidewall of the nozzle body 470. Referring to FIG. 10, the nozzle 440 may further include a second cleaning liquid entrance port 492 on another sidewall of the nozzle body 470. The second cleaning liquid entrance port 492 may be disposed in the same direction in which the first cleaning liquid entrance port 490 is disposed. For example, the first and second cleaning liquid entrance ports 490 and 492 may be disposed in the first direction x. A second cleaning liquid line fitting 456 may be mounted on the second cleaning liquid entrance port 492. The cleaning liquid 452 may be provided into the internal passage 510 through the second cleaning liquid line pitting 456 and the second cleaning liquid entrance port 492. The second cleaning liquid entrance port 492 may have a diameter that is the same as the second diameter D₂ of the first cleaning liquid entrance port 490. For example, the second diameter D₂ of each of the first and second cleaning liquid entrance ports 490 and 492 may fall within a range from about 1.8 mm to about 2.5 mm. The third diameter D₃ of the fluid injection port 500 may be about 1.2 to 1.7 times greater than the second diameter D₂. When the second diameter D₂ is about 1.8 mm, the third diameter D₃ may be about 3 mm. When the second diameter D₂ is about 2.5 mm, the third diameter D₃ may be about 4.25 mm.

The gas line fitting 464, the first cleaning liquid line fitting 454, the nozzle body 470, the gas entrance port 480, the fluid injection port 500, and the internal passage 510 may be configured identically to those discussed above with reference to FIG. 5.

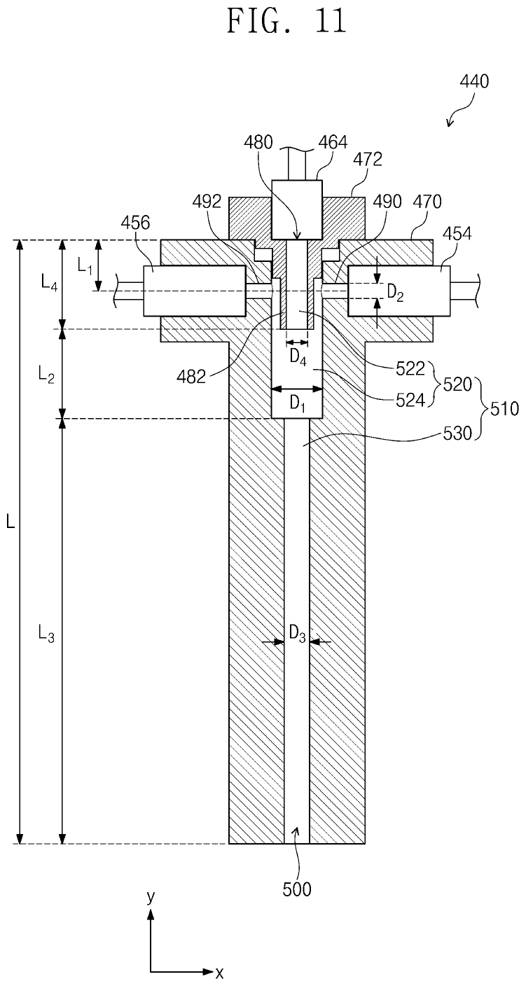

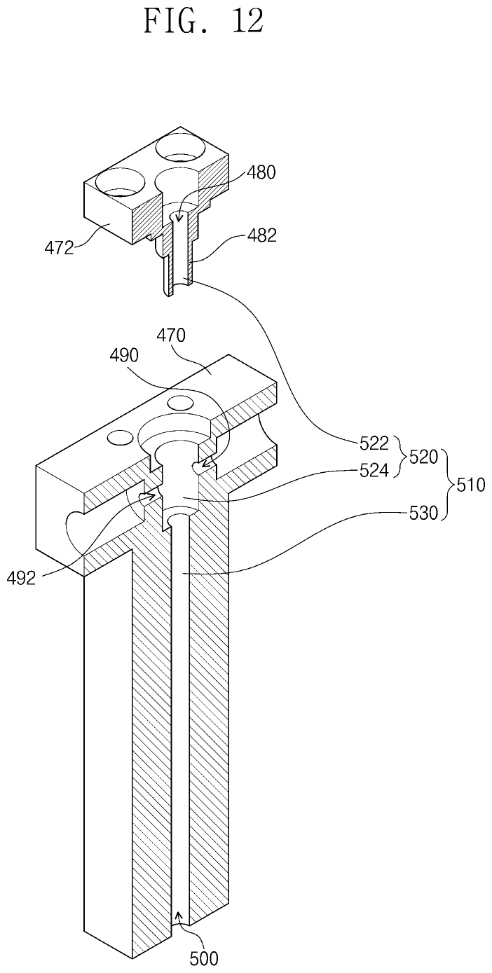

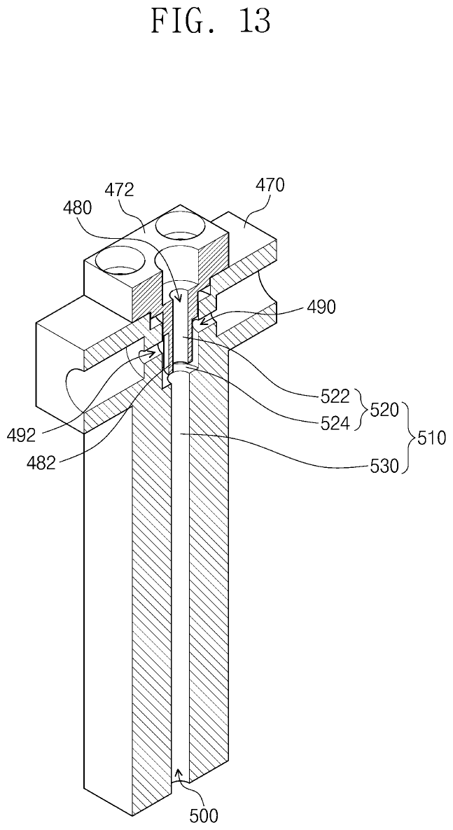

FIG. 11 is a cross-sectional view illustrating an example of the nozzle 440 shown in FIG. 2. FIGS. 12 and 13 are exploded and combined perspective views of FIG. 11.

Referring to FIGS. 11 to 13, the nozzle 440 may include a gas supply block 472 engaged with the nozzle body 470. According to an exemplary embodiment of the present disclosure, the gas supply block 472 may have a gas supply tube 482. The gas supply tube 482 may be provided in or inserted into the fluid supply zone 520 of the internal passage 510. The gas 462 of FIG. 2 may be provided through the gas line fitting 464 into the gas supply tube 482.

The gas entrance port 480 may have a fourth diameter D₄, and the gas supply tube 482 may have an inner diameter that is the same as the fourth diameter D₄. The inner diameter D₄ of the gas supply tube 482 may be greater than the second diameter D₂ of each of the first and second cleaning liquid entrance ports 490 and 492. The inner diameter D₄ of the gas supply tube 482 may be less than the third diameter D₃ of the fluid injection port 500. For example, the inner diameter D₄ of the gas supply tube 482 may be about 1.2 to 1.4 times greater than the second diameter D₂ and about 60% to 80% of the size of the third diameter D₃. When the inner diameter D₄ of the gas supply tube 482 is in a range of about 2.5 mm to about 3 mm, the second diameter D₂ may fall within a range from about 1.8 mm to about 2.5 mm, and the third diameter D₃ may fall within a range from about 3 mm to about 4.5 mm.

The gas supply tube 482 may have an outer diameter that is less than the first diameter D₁ of the fluid supply zone 520. When the first diameter D₁ of the fluid supply zone 520 is in a range of about 3 mm to about 8 mm, the outer diameter of the gas supply tube 482 may fall within a range from about 2.5 mm to about 4 mm.

The gas supply tube 482 may extend downwardly over the first and second cleaning liquid entrance ports 490 and 492. According to an exemplary embodiment of the present inventive concept, the gas supply tube 482 may have a fourth length L₄. The fourth length L₄ may be greater than a first length L₁ from the gas entrance port 480 to a center of each of the first and second cleaning liquid entrance ports 490 and 492. For example, the fourth length L₄ may be about 2 to 3 times greater than the first length L₁. When the first length L₁ is about 5 mm, the fourth length L₄ may fall within a range from about 10 mm to about 15 mm.

The fluid mixture zone 524 of the internal passage 510 may be defined between the gas supply tube 482 and the fluid acceleration zone 530. The fluid mixture zone 524 may have a second length L₂. The second length L₂ may be in a range of about 5 mm to about 10 mm. In such a configuration, the cleaning liquid 452 in the first and second cleaning liquid entrance ports 490 and 492 may flow along an outer surface of the gas supply tube 482 and an inner wall of the internal passage 510, and may thus be introduced into the fluid mixture zone 524.

The fluid acceleration zone 530 of the internal passage 510 and the first and second cleaning liquid line fittings 454 and 456 may be configured identically to those discussed above with reference to FIGS. 5 and 10.

A method of manufacturing a semiconductor device using the semiconductor device manufacturing facility 100 of FIG. 1 is described in detail below.

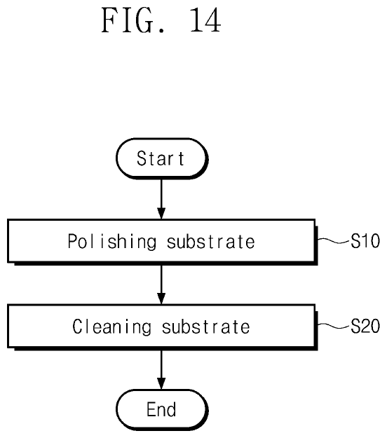

FIG. 14 shows a method of manufacturing a semiconductor device, according to exemplary embodiments of the present inventive concept.

Referring to FIGS. 1, 2, and 14, a method of manufacturing a semiconductor device may include polishing the substrate W (S10) and cleaning the substrate W (S20).

First, the polishing apparatus 130 may polish the substrate W (S10). The polishing apparatus 130 may use a slurry to chemically and mechanically polish the substrate W. The transfer arm 125 may transfer the substrate W to the cleaning apparatus 140.

Next, the cleaning apparatus 140 may clean the substrate W (S20). The cleaning apparatus 140 may use the spray 442 of the cleaning liquid 452 to wet clean the substrate W. The nozzle 440 may receive the cleaning liquid 452 at a pressure of about 2 bars, and also receive the gas 462 at a pressure of about 4 bars. The nozzle 440 may clean the substrate W with an efficiency equal to or greater than the threshold value of the particle removal efficiency. The cleaning apparatus 140 may use a brush to clean the substrate W. The transfer arm 125 may transfer the substrate W to a drying apparatus. The drying apparatus may dry the substrate W. Thereafter, the index arm 116 may bring the substrate W into the carrier 118.

According to exemplary embodiments of the present inventive concept, a cleaning liquid nozzle may use a fluid injection port whose diameter is less than that of a gas entrance port and greater than that of a cleaning liquid entrance port, and thus particle removal efficiency may be increased to about 98% or higher.

Although exemplary embodiments of the present invention have been described herein in connection with the accompanying drawings, it will be understood to those skilled in the art that various changes and modifications may be made without departing from the technical spirit and features of the present disclosure.

What is claimed is:

1. A cleaning liquid nozzle, comprising:
a nozzle body;
an internal passage which extends in a first direction, the internal passage including a fluid supply zone and a fluid acceleration zone which is connected to the fluid supply zone;
a first cleaning liquid entrance port disposed on one sidewall of the nozzle body and connected to the fluid supply zone;
a second cleaning liquid entrance port disposed on another sidewall of the nozzle body and connected to the fluid supply zone; and
a gas supply block engaged with the nozzle body,
wherein the gas supply block has a gas supply tube which is inserted into the fluid supply zone and extends in the first direction over the first cleaning liquid entrance ports,
wherein the fluid supply zone has a first diameter, the first cleaning liquid entrance port has a second diameter less than the first diameter, and the fluid acceleration zone has a third diameter less than the first diameter,
wherein the gas supply tube has an inner diameter greater than the second diameter, and an outer diameter less than the first diameter,
wherein the outer diameter of the gas supply tube is constant from a middle position between the first cleaning liquid entrance port and the second cleaning liquid entrance port to a bottommost position.

2. The cleaning liquid nozzle of claim 1, wherein the inner diameter of the gas supply tube is 1.2 to 1.4 times greater than the second diameter.

3. The cleaning liquid nozzle of claim 2, wherein the second diameter is 1.8 mm to 2.5 mm when the inner diameter of the gas supply tube is 2.5 mm to 3 mm.

4. The cleaning liquid nozzle of claim 1, wherein the inner diameter of the gas supply tube is 0.6 to 0.8 times less than the third diameter.

5. The cleaning liquid nozzle of claim 4, wherein the third diameter is 3 mm to 4.5 mm when the inner diameter of the gas supply tube is 2.5 mm to 3 mm.

6. The cleaning liquid nozzle of claim 1, wherein an outer surface of the gas supply tube is parallel to the first direction.

7. The cleaning liquid nozzle of claim 1, wherein a length of the gas supply tube is less than a length of the fluid supply zone.

8. The cleaning liquid nozzle of claim 7, wherein the length of the gas supply tube is 10 mm to 15 mm.

9. The cleaning liquid nozzle of claim 7, wherein the length of the fluid supply zone is 10 mm to 30 mm.

10. The cleaning liquid nozzle of claim 1, wherein the third diameter is 1.2 to 1.7 times greater than the second diameter.

11. A cleaning apparatus, comprising:
a gas supply line providing a gas;
a cleaning liquid supply line providing a cleaning liquid; and
a nozzle connected to both the gas supply line and the cleaning liquid supply line, the nozzle configured to apply the cleaning liquid to a substrate,
wherein the nozzle comprises:
a nozzle body;
an internal passage which extends in a first direction, the internal passage including a fluid supply zone and a fluid acceleration zone which is connected to the fluid supply zone;
a first cleaning liquid entrance port disposed on one sidewall of the nozzle body and connected to the fluid supply zone;
a second cleaning liquid entrance port disposed on another sidewall of the nozzle body and connected to the fluid supply zone; and
a gas supply block engaged with the nozzle body,
wherein the gas supply block has a gas supply tube which is inserted into the fluid supply zone and extends in the first direction,
wherein the fluid supply zone has a first diameter, the first cleaning liquid entrance port has a second diameter less than the first diameter, and the fluid acceleration zone has a third diameter less than the first diameter,
wherein the gas supply tube has an inner diameter greater than the second diameter, and an outer diameter less than the first diameter,
wherein a bottommost outer diameter of the gas supply tube is equal to a middle outer diameter of the gas supply tube between the first cleaning liquid entrance port and the second cleaning liquid entrance port.

12. The cleaning apparatus of claim 11, wherein the gas includes Ar.

13. The cleaning apparatus of claim 11, wherein the cleaning liquid includes de-ionized water containing CO2.

14. The cleaning apparatus of claim 11, wherein a pressure of the gas is equal to or greater than 3 bars.

15. The cleaning apparatus of claim 11, wherein a pressure of the cleaning liquid is 3 bars.

16. A cleaning liquid nozzle, comprising:
a nozzle body;
an internal passage which extends in a first direction, the internal passage including a fluid supply zone and a fluid acceleration zone which is connected to the fluid supply zone;
a first cleaning liquid entrance port disposed on one sidewall of the nozzle body and connected to the fluid supply zone;
a second cleaning liquid entrance port disposed on another sidewall of the nozzle body and connected to the fluid supply zone; and
a gas supply block engaged with the nozzle body,
wherein the gas supply block has a gas supply tube which is inserted into the fluid supply zone and extends in the first direction,
wherein the gas supply tube has an inner diameter greater than the second diameter, and an outer diameter less than a first diameter of the fluid supply zone,
wherein an outer surface of the gas supply tube is parallel to the first direction from a position between the first cleaning liquid entrance port and the second cleaning liquid entrance port to a bottommost position.

17. The cleaning liquid nozzle of claim 16, wherein a length of the gas supply tube is 10 mm to 15 mm.

18. The cleaning liquid nozzle of claim 16, wherein the nozzle body comprises a metal or is formed of carbon nanotubes.
